(19) United States
(12) Patent Application Publication
(10) Pub. No.: US 2008/0237874 A1
(43) Pub. Date: Oct. 2, 2008

(54) Method of Producing a Silicon Oxide-Based Material with a Low Dielectric Constant

(76) Inventors: Esidor Ntsoenzok, Olivet (FR); Hanan Assaf, Nabatieh (LB); Marie-Odile Ruault, Saint Jean De Beauregard (FR)

Correspondence Address: Howard IP Law Group, P.O. Box 226, Fort Washington, PA, 19034, US

(21) Appl. No.: 11/883,037

(22) PCT Filed: Jan. 27, 2006
(86) PCT No.: PCT/FR2006/050067

§ 371 Date: Jun. 5, 2008

(30) Foreign Application Priority Data
Jan. 28, 2005 (FR) 0550253

(51) Int. Cl. H01L 23/48; H01L 21/425

(52) U.S. Cl. 257/773; 438/527; 257/E21.473; 257/E23.01

(57) ABSTRACT

A method for manufacturing a material with a low dielectric constant, comprising a step of forming cavities in silicon dioxide by implantation of a rare gas different from helium and from neon at an implantation dose greater than 10¹⁶ atoms/cm².

### FIELD OF THE INVENTION

The present invention relates to a method for manufacturing a silicon-oxide-based material with a low dielectric constant, especially to form integrated circuits. The present invention also relates to a silicon-oxide-based material with a low dielectric constant obtained by such a method.

### DISCUSSION OF PRIOR ART

FIG. 1 very schematically shows an example of a conventional integrated circuit 10. As usual in the representation of integrated circuits, FIG. 1 is not drawn to scale. As an example, integrated circuit 10 comprises a substrate 12, for example made of single-crystal silicon comprising doped regions 14, 16. A MOS-type transistor 15 is shown at the level of the surface of substrate 12 and comprises a gate oxide portion 18, for example made of silicon oxide, covered with a gate portion 20, for example made of polysilicon. Doped regions 14, 16 form the source and the drain of MOS transistor 15. Substrate 10 and MOS transistor 15 are covered with an insulating layer 22 on which are arranged metal tracks 24 (two tracks being shown in FIG. 1) of a first metallization level. Doped regions 14, 16 are connected to tracks 24 via metal contacts 25. Insulating layer 22 and tracks 24 are covered with an insulating layer 26 on which are formed metal tracks 28 (three tracks 28 being shown in FIG. 1) of a second metallization level. Metal vias 29 ensure the connection between tracks 28 and tracks 24. Insulating layer 26 and tracks 28 are covered with an insulating layer 30.

Generally in integrated circuit manufacturing methods, insulating layers 22, 26, 30 are formed of silicon oxide (SiO₂) and are, for example, obtained by chemical vapor deposition (CVD).

The propagation speed of a signal in an integrated circuit is mainly limited by the response times of the transistors and the response times of the interconnects between transistors, that is, the response time of the tracks, of the contacts, and of the vias. The response time of an interconnect may be determined based on time constant RC of the interconnect, where R corresponds to the interconnect resistance and C corresponds to the capacitance of the insulating material surrounding the interconnect.

FIG. 2 shows a curve 40 of variation of delay T introduced by a MOS transistor of an integrated circuit and curves 42, 44 of variation of the delay introduced by a metal track respectively of a 3,000-μm and of a 5,000-μm length according to a characteristic dimension D of the conventional integrated circuit. Characteristic dimension D of the integrated circuit generally corresponds to the channel length (source-drain distance) of the transistors which form it.

The current tendency is to form integrated circuits having the smallest possible characteristic dimension. There appears from FIG. 2 that when the characteristic dimension of the integrated circuit decreases below one micrometer, the delay introduced by the interconnects becomes preponderating with respect to the delay due to the MOS transistors.

A solution to decrease the delay due to interconnects comprises forming the interconnects with a material of low resistivity. This is especially a reason why aluminum, currently used to form the interconnects, tends to be replaced with copper. This however appears to be insufficient.

Another solution comprises replacing the silicon dioxide with a material of lower dielectric constant. A first example of a material with a low dielectric constant is porous silica. However, a disadvantage of porous silica is that it has a low mechanical resistance and tends to absorb the ambient humidity. A second example of a material with a low dielectric constant corresponds to polyimides. However, a disadvantage of polyimides is that they tend to mould and have strongly anisotropic electric properties. The use of porous silica or of polyimides to form the insulating layers of an integrated circuit does not provide reliable structures and is relatively delicate.

Further, methods for manufacturing and processing silicon dioxide are well controlled and perfectly compatible with current integrated circuit manufacturing methods. It would thus be desirable to keep silicon dioxide as the integrated circuit insulator.

The present invention aims at a method for manufacturing a silicon-oxide-based material having a decreased dielectric constant and having mechanical resistance and humidity absorption properties similar to those of conventional silicon dioxide.

According to another object, the present invention aims at a method which is compatible with currently-implemented integrated circuit manufacturing methods.

The present invention also aims at a silicon-dioxide-based material and with a low dielectric constant having mechanical resistance and humidity absorption properties similar to those of conventional silicon dioxide.

### SUMMARY OF THE INVENTION

For this purpose, the present invention provides a method for manufacturing a material with a low dielectric constant, comprising a step of forming cavities in silicon dioxide by implantation of a rare gas different from helium and from neon at an implantation dose greater than 10¹⁶ atoms/cm².

According to an embodiment of the present invention, the gas is xenon or krypton.

According to an embodiment of the present invention, the method comprises several successive steps of implantation of said rare gas.

According to an embodiment of the present invention, said implantation is performed at an implantation dose selected according to the desired average diameter of the cavities.

According to an embodiment of the present invention, the cavities are located in depth in a portion of the silicon dioxide, said implantation being performed at an implantation dose and at an implantation power selected according to the desired dimensions of said portion.

The present invention also provides a component comprising metal tracks and regions separating said metal tracks, said regions containing silicon dioxide with a low dielectric constant comprising cavities formed by implantation of a rare gas different from helium and from neon.

According to an embodiment of the present invention, the cavities are located in depth in said regions.

### BRIEF DESCRIPTION OF THE DRAWINGS

The foregoing and other objects, features, and advantages of the present invention will be discussed in detail in the following non-limiting description of specific embodiments in connection with the accompanying drawings, among which:

FIG. 1, previously described, very schematically shows an example of an integrated circuit;

FIG. 2, previously described, shows the variation of the delays, on transmission of a signal, due to some components of an integrated circuit according to a characteristic dimension of an integrated circuit;

FIG. 3 illustrates an example of a method for manufacturing according to the present invention a silicon-oxide-based material with a low dielectric constant according to the present invention;

FIG. 4 very schematically shows the structure of a layer of a silicon-oxide-based material with a low dielectric constant according to the present invention; and

FIGS. 5 and 6 show the variation of characteristics of a silicon-oxide-based material with a low dielectric constant according to the present invention according to temperature.

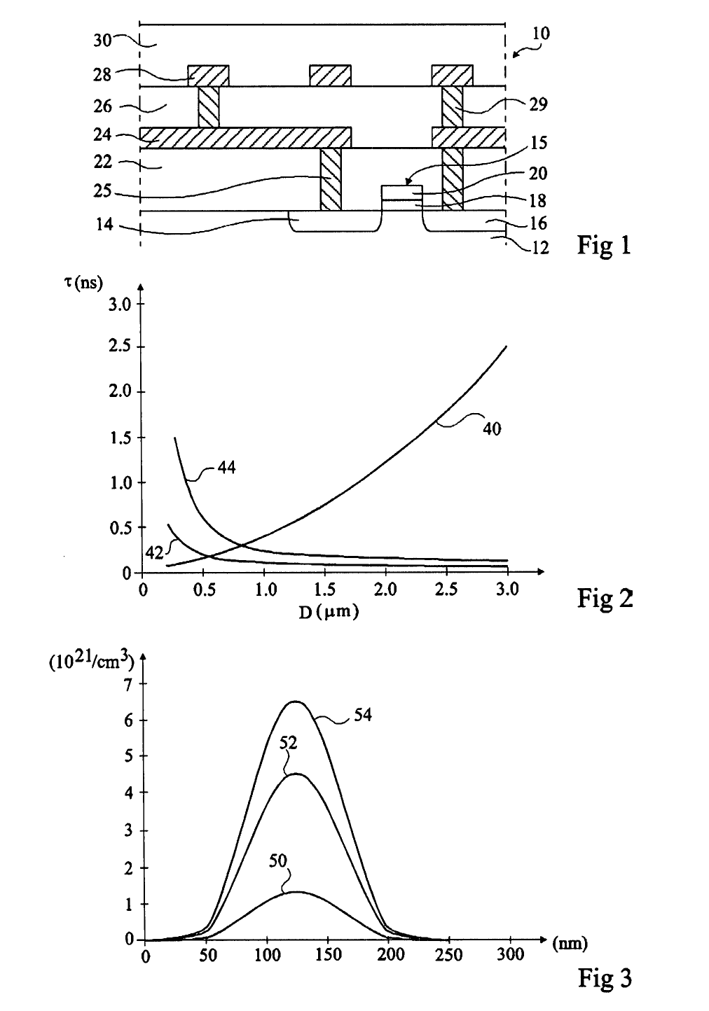

### DETAILED DESCRIPTION

To decrease the dielectric constant of a silicon-oxide-based material, the present invention comprises forming cavities, or bubbles, in silicon dioxide. The presence of such cavities provides a material with a low dielectric constant. According to the present invention, the forming of the cavities is obtained by implantation of ions of a rare gas into the silicon dioxide. Indeed, the applicant has highlighted the forming of cavities in the silicon dioxide when the rare gas implantation is performed under specific conditions. A first condition bears on the selection of the rare gas. Indeed, the applicant has shown the absence of the forming of cavities with a helium or neon implantation. The forming of cavities in the silicon oxide has been obtained with an implantation of a rare gas having an atomic number strictly greater than that of neon, for example, argon, krypton, or xenon.

A specific example of the forming of cavities in a silicon dioxide layer will now be described in the case of the implantation of xenon.

FIG. 3 shows curves 50, 52, 54 obtained by simulation, representative of the variation of the expected xenon concentration according to the depth in a silicon dioxide layer having a 220-nanometer thickness, obtained by thermal oxidation of a silicon substrate, respectively for the following implantation doses: 1*10¹⁶ atoms/cm², 3.5*10¹⁶ atoms/cm², and 5*10¹⁶ atoms/cm² and for a 150-keV power. The maximum concentration depth, or implantation depth, appears to be substantially constant whatever the used dose and is on the order of 125 nanometers.

The applicant has highlighted the forming of cavities across the silicon dioxide depth from as soon as the dose is greater than 1*10¹⁶ atoms/cm². The minimum dose depends on the used implantation power and increases along with the implantation power.

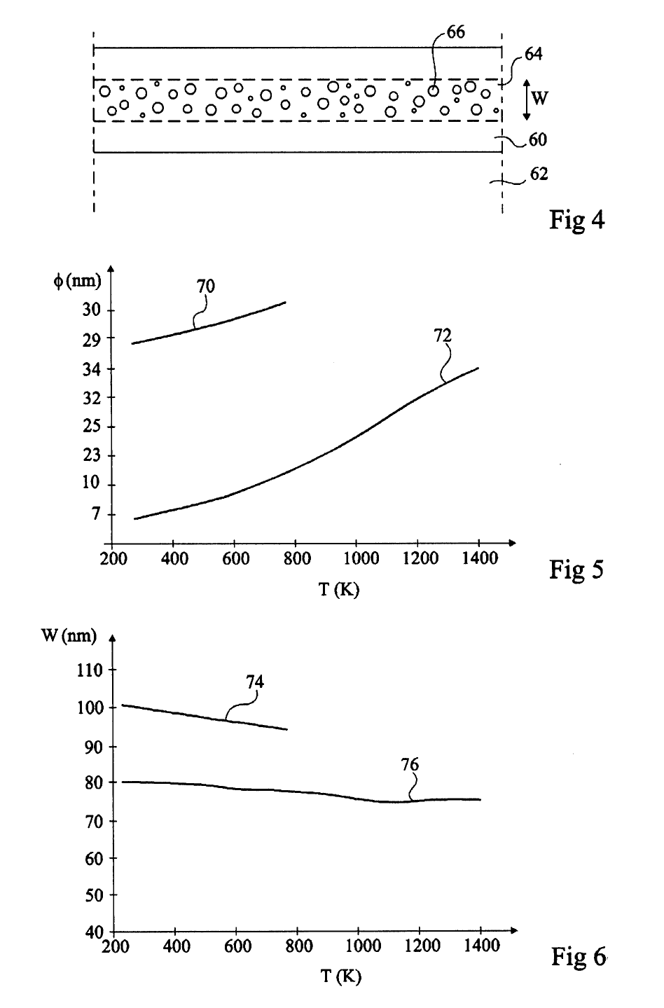

FIG. 4 very schematically shows a silicon dioxide layer 60 covering a silicon substrate 62. Silicon dioxide layer 60 is, for example, obtained by thermal oxidation of a portion of substrate 62. After implantation of rare gas with an adapted dose and power, a strip 64 of thickness W containing substantially spherical cavities 66 is obtained in silicon dioxide layer 60. Note Φ the average diameter of cavities 66 in strip 64. All other conditions being equal, average diameter Φ of cavities 66 and thickness W of strip 64 increase along with the rare gas implantation dose.

The measurement of the dielectric constant of the silicon dioxide layer 60 thus obtained may be performed by forming a MOS transistor having its gate oxide formed by silicon dioxide layer 60. For this purpose, a metal pad, not shown, is formed on silicon dioxide layer 60 which forms the gate contact of the MOS transistor. Capacitance Cₘₑₛ of the MOS transistor is then measured by means of the capacitance-voltage method (C-V) by application of a voltage (voltage V_{GB}) between the gate contact and substrate 62. Capacitance C_{OX} of the gate oxide, that is, the capacitance of silicon dioxide layer 60 obtained according to the method of the invention, can thus be deduced therefrom. Indeed, generally, capacitance Cₘₑₛ of the MOS transistor is given by the following relation:

$$\frac{1}{{C}_{mes}} = \frac{1}{{C}_{ox}} + \frac{1}{{C}_{SC}}$$

where C_{SC} is the capacitance of semiconductor substrate 62. Capacitance C_{SC} varies according to the voltage V_{GB} applied while capacitance C_{OX} is constant.

It can be shown that when voltage V_{GB} is much lower than the flat band voltage of the transistor, capacitance C_{SC} is much greater than capacitance C_{OX} so that one obtains:

$$\frac{1}{{C}_{mes}} \approx \frac{1}{{C}_{ox}}$$

Dielectric constant K of silicon dioxide layer 60 can be deduced from the expression of capacitance C_{OX} by the following relation:

$${C}_{ox} = ɛ \frac{S}{e} = {ɛ}_{0} K \frac{S}{e}$$

where S is the surface area of the metal pad, e is the thickness of silicon dioxide layer 60 and ε₀ is the electric constant, equal to 8.85.10⁻¹² F/m.

For a silicon dioxide layer 60 having undergone a xenon implantation with a 3.5*10¹⁶-atoms/cm² dose, a 150-keV implantation power and in the absence of any anneal, a dielectric constant K equal to 1.54 is measured. In the absence of cavities, the dielectric constant of a silicon dioxide layer is approximately 4.2. A strong decrease in dielectric constant K can thus be observed. The applicant has also shown that by increasing the dose used for the implantation, or by performing several successive implantations, the dielectric constant can be further decreased still. As an example, for a silicon dioxide layer 60 having undergone a xenon implantation with a 5*10¹⁶-atoms/cm² dose, a dielectric constant K equal to 1.4 is measured in the absence of any anneal or else with an anneal performed up to 300° C. and for 1 hour.

Further, the applicant has studied the evolution of cavities 66 obtained by the implantation method according to the present invention according to temperature.

FIG. 5 shows curves 70, 72 of variation of average diameter Φ of cavities 66 according to temperature T of an anneal of silicon dioxide layer 60 respectively for a xenon implantation dose of 5*10¹⁶ atoms/cm² and 3.5*10¹⁶ atoms/cm², and FIG. 6 shows curves 74, 76 of variation of thickness W of cavity strip 64 according to anneal temperature T respectively for a xenon implantation dose of 5*10¹⁶ atoms/cm² and 3.5*10¹⁶ atoms/cm².

For the two examples of implantation doses, an increase in average diameter Φ of cavities 66 forming in silicon dioxide layer 60 according to anneal temperature T can be observed. However, no significant variation of thickness W of cavity strip 64 according to anneal temperature T can be observed. Further, it can be acknowledged that, for a given anneal temperature, average diameter Φ of cavities 66 and thickness W of cavity strip 64 increase along with the used dose.

The applicant has shown that after an anneal performed at a temperature lower than 1,100° C., xenon remains present in cavities 66 formed in silicon dioxide layer 60. When the anneals is performed at a temperature greater than 1,100° C., a strong desorption of xenon occurs. However, the maintaining of cavities 66 in silicon dioxide layer 60 can be observed. The present invention thus enables obtaining cavities 66 which can be kept even at high temperatures.

Another specific example of the forming of cavities in a silicon dioxide layer will now be described in the case of a krypton implantation. The applicant has highlighted the forming of cavities in a silicon dioxide layer from as soon as the krypton dose is greater than 1*10¹⁶ atoms/cm².

As an example, for a silicon dioxide layer having a thickness of approximately 220 nm and having undergone a krypton implantation with a 5*10¹⁶-atoms/cm² dose and a 220-keV implantation power and in the absence of any anneal, the applicant has shown the forming of a wide strip of cavities having a thickness of approximately 150 nm and entered at approximately 110 nm from the surface of the silicon dioxide layer. The applicant has observed a homogeneous distribution of the cavities in such a cavity strip. The average cavity radius is on the order of 5 nm.

The measured dielectric constant K is equal to 1.6. A strong decrease in the dielectric constant with respect to the dielectric constant measured in the absence of cavities (approximately 4.2) can thus be observed.

Another specific example of the forming of cavities in a silicon dioxide layer will now be described in the case of the implantation of argon. The applicant has highlighted the forming of cavities in a silicon dioxide layer as soon as the argon dose is greater than 1*10¹⁶ atoms/cm².

As an example, for a silicon dioxide layer of a 170-nm thickness having undergone an argon implantation with a 5*10¹⁶-atoms/cm² dose and a 100-keV implantation power and in the absence of any anneal, the applicant has shown the forming of a cavity strip having a thickness of approximately 80 nm. More specifically, the forming of a single layer of cavities located at approximately 72 nm from the surface of the silicon dioxide layer can be obtained. In the single layer of cavities, the average cavity radius is approximately 4 nm. The single layer of cavities extends in depth into the silicon dioxide layer in a strip of smaller cavities. The average cavity radius in the strip of smaller cavities is smaller than 2.5 nm.

The measured dielectric constant K is equal to 1.6. A strong decrease in the dielectric constant can thus be observed with respect to the dielectric constant measured in the absence of cavities (approximately 4.2).

The present invention has many advantages:

first, it enables decreasing the dielectric constant of silicon dioxide, which is the material most currently used as an insulator in integrated circuits;

second, the dielectric constant decrease can be accurately controlled by varying the implantation power, the implantation dose, and/or the number of implantations;

third, the method according to the present invention, which comprises a step of rare gas implantation, is quite compatible with a conventional integrated circuit manufacturing method, which generally already comprises several implantation steps;

fourth, the method according to the present invention can be implemented at ambient temperature, the cavities formed in the implantation step remaining even at high temperatures;

fifth, since the cavities form in depth in the silicon dioxide and not at the surface thereof, the material with a low dielectric constant according to the present invention has a humidity absorption property comparable to that of unprocessed silicon dioxide; and

sixth, since the cavities are located in an accurately-delimited region, the material with a low dielectric constant obtained according to the present invention has a mechanical performance comparable to that of unprocessed silicon dioxide or little altered with respect thereto.

Of course, the present invention is likely to have various modifications and variations which will occur to those skilled in the art. In particular, the present invention has been described in the case of the implantation of a rare gas in silicon oxide obtained by thermal oxidation of a silicon substrate. It should be clear that the present invention may also apply to the case where silicon oxide is obtained by chemical vapor deposition (CVD method), the implantation powers and doses then having to be adapted accordingly.

1. A method for manufacturing a material with a low dielectric constant, comprising a step of forming cavities in silicon dioxide by implantation of a rare gas different from helium and from neon at an implantation dose greater than 10¹⁶ atoms/cm².

2. The method of claim 1, in which the gas is xenon.

3. The method of claim 1, in which the gas is krypton.

4. The method of claim 1, in which the gas is argon.

5. The method of claim 1, comprising several successive steps of implantation of said rare gas.

6. The method of claim 1, in which said implantation is performed at an implantation dose selected according to the desired average diameter of the cavities.

7. The method of claim 1, in which the cavities (66) are located in depth in a portion of the silicon dioxide, said implantation being performed at an implantation dose and at an implantation power selected according to the desired dimensions of said portion.

8. A component comprising metal tracks and regions separating said metal tracks, said regions containing silicon dioxide with a low dielectric constant comprising cavities formed by implantation of a rare gas different from helium and from neon at an implantation dose greater than 10¹⁶ atoms/cm².

9. The component of claim 8, in which the cavities are located in depth in said regions.
